(19) United States
(12) Patent Application Publication
(10) Pub. No.: US 2007/0072310 A1
(43) Pub. Date: Mar. 29, 2007

(54) Semiconductor device and method of manufacturing the same

(76) Inventors: Yoshinori Kumura, Yokohama-shi (JP); Tohru Ozaki, Tokyo (JP); Susumu Shuto, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/364,224

(22) Filed: Mar. 1, 2006

(30) Foreign Application Priority Data
Sep. 28, 2005 (JP) 2005-281694

(51) Int. Cl. H01L 21/00; H01L 21/8242; H01L 29/94; H01L 27/108; H01L 29/76; H01L 31/119

(52) U.S. Cl. 438/3; 438/239; 257/310; 257/306

(57) ABSTRACT

A semiconductor device comprising a semiconductor substrate and memory cells. Each memory cell comprises a switching transistor and a ferroelectric capacitor, both formed on the substrate. The ferroelectric capacitor includes a lower electrode, an upper electrode and a ferroelectric film held between the lower and upper electrodes. A first wire formed from a deposited wire-material film is connected to the upper electrode of the ferroelectric capacitor. A second wire formed by damascene process is provided on the first wire.

### CROSS-REFERENCE TO RELATED APPLICATIONS

This application is based upon and claims the benefit of priority from prior Japanese Patent Application No. 2005-281694, filed Sep. 28, 2005, the entire contents of which are incorporated herein by reference.

### BACKGROUND OF THE INVENTION

1. Field of the Invention

The present invention relates to a semiconductor device such as a ferroelectric random access memory (FeRAM) having ferroelectric capacitors, and to a method of manufacturing this semiconductor conductor device.

2. Description of the Related Art

In recent years, the integration density of dynamic random access memories (DRAMs) has increased. As the integration density increases, the capacitance of each element is approaching its lower limit (i.e., the smallest capacitance below which the element can no longer operate). Hence, nonvolatile semiconductor memories having ferroelectric capacitors, such as FeRAMs, are being developed as devices in which elements can operate even at a smaller capacitance. Cu wires are used, achieving multi-layer wiring technology for logic elements of, for example, 130-nm design.

Damascene process is performed to provide a hybrid device that comprises an FeRAM and logic elements having Cu wires (see Nikkei Microdevice, July 2004, pp. 53-55). The damascene process comprises the following steps. First, a contact plug is formed on each ferroelectric capacitor. Next, an interlayer insulating film is deposited on the capacitor and the contact plug. Then, RIE is performed on the interlayer insulating layer, making a wiring groove for a first wire in the insulating layer. Finally, Cu is deposited in the wiring groove.

During the RIE for providing a Cu wire on each ferroelectric capacitor, the upper electrode of the ferroelectric capacitor is exposed to the plasma. Since the ferroelectric capacitor floating before the first wire is connected, the charge resulting from the plasma is accumulated in the upper electrode of the ferroelectric capacitor. The charge accumulated in the ferroelectric capacitor degrades the switching and in-print characteristics of the ferroelectric capacitor. Due to such charging damages, the damascene structure on the ferroelectric capacitor cannot impart good ferroelectric characteristic to the ferroelectric capacitor.

In any conventional semiconductor memory that comprises ferroelectric capacitors, charging damages develop because the memories have damascene structure. The charging damages degrade the element characteristics of the memories. Particularly in high-performance logic cells, multi-layer Cu wiring must be provided. Hence, with the conventional techniques it is difficult to mount an FeRAM and high-performance logic elements on the same substrate. This problem is inherent not only to nonvolatile semiconductor memories such as FeRAMs, but also to various semiconductor memories that have ferroelectric capacitors.

### BRIEF SUMMARY OF THE INVENTION

According to an aspect of this invention, there is provided a semiconductor device comprising:

a semiconductor substrate;

a switching transistor which is formed on the substrate;

a ferroelectric capacitor which is formed on the substrate and includes a lower electrode, an upper electrode and a ferroelectric film held between the lower and upper electrodes;

a first wire which is formed on the ferroelectric capacitor, electrically connected to the upper electrode of the ferroelectric capacitor, and formed by processing a wire-material film deposited; and

a second wire which is provided on the first wire and formed by damascene process.

According to another aspect of the invention, there is provided a semiconductor device comprising:

a semiconductor substrate;

a memory cell section which is formed on a region of the substrate and has a memory cell that comprises a switching transistor and a ferroelectric capacitor including a lower electrode, an upper electrode and a ferroelectric film held between the lower and upper electrodes;

a peripheral cell section which is formed on another region of the substrate and has a transistor;

a first wire which is connected to the upper electrode of the ferroelectric capacitor and formed by processing a wire-material film deposited; and

a second wire which is formed in the peripheral section and formed by damascene process.

According to still another aspect of the invention, there is provided a method of manufacturing a semiconductor device, comprising:

forming a switching transistor on a semiconductor substrate;

depositing a first interlayer insulating film on the substrate, covering the transistor;

forming a lower electrode, a ferroelectric film and an upper electrode on the first interlayer insulating film, sequentially one on another, thereby providing a ferroelectric capacitor;

depositing a second interlayer insulating film on the first interlayer insulating film, covering the ferroelectric capacitor;

forming a plug electrode in the second interlayer insulating film, the plug electrode being electrically connected to the upper electrode of the ferroelectric capacitor;

forming a conductive film on the second interlayer insulating film and the plug electrode;

patterning the conductive film, thereby forming a first wire; and

forming a second wire on the first wire by means of damascene process.

### BRIEF DESCRIPTION OF THE SEVERAL VIEWS OF THE DRAWING

FIG. 1 is a sectional view showing the structure of an FeRAM cell according to a first embodiment of the present invention;

FIG. 2 is a sectional view showing the structure of an FeRAM cell according to a second embodiment of the invention;

FIG. 3 is a sectional view depicting the structure of an FeRAM cell according to a third embodiment of this invention;

FIG. 4 is a sectional view illustrating the structure of an FeRAM cell according to a fourth embodiment of the invention;

FIG. 5 is a sectional view showing the structure of an FeRAM cell according to a fifth embodiment of this invention;

FIG. 6 is a sectional view showing the structure of an FeRAM cell according to a sixth embodiment of the invention;

FIG. 7 is a sectional view depicting the structure of an FeRAM cell according to a seventh embodiment of the present invention;

FIG. 8 is a sectional view showing the structure of an FeRAM cell according to an eighth sixth embodiment of this invention;

FIG. 9 is a sectional view illustrating the structure of an FeRAM cell according to a ninth embodiment of the invention;

FIG. 10 is a sectional view showing the structure of an FeRAM cell according to a tenth embodiment of this invention; and

FIGS. 11A to 11J are sectional views explaining the steps of manufacturing an FeRAM cell according to an eleventh embodiment of the present invention.

### DETAILED DESCRIPTION OF THE INVENTION

Embodiments of this invention will be described in detail, with reference to the accompanying drawings.

### First Embodiment

FIG. 1 is a sectional view that shows the structure of an FeRAM cell according to the first embodiment of this invention. The structure comprises a silicon substrate 100, a ferroelectric memory cell section 10 and a logic cell section (peripheral cell section) 20, which are shown in the left and right parts of FIG. 1, respectively. This embodiment is a ferroelectric memory that comprises TC unit cells connected in series. Each unit cell comprises a capacitor (C) and a cell transistor (T). The capacitor is provided between the source and drain of the cell transistor, with its ends connected to the source and drain, respectively.

The silicon substrate 100 has shallow trench isolation (STI) regions (not shown), which isolates the elements. A gate insulating film 101 made of, for example, SiO₂, is formed on the entire upper surface of the silicon substrate 100. In the cell sections 10 and 20, a lower gate electrode 102, a lower gate electrode 103 and a cap layer 104 are provided, one on another in the order mentioned, on a part of the gate insulating film 101. The lower gate electrode 102 is made of polycrystalline silicon. The upper gate electrode 103 is made of W silicide. The cap layer 104 is an SiN film.

Sidewall-insulating films 105 are formed on the sidewalls of the gate section, which comprises the gate electrodes 102 and 103 and the cap layer 104. A source diffusion layer and a drain diffusion layer are formed in the surface of the substrate 100. The gate section lies between the source diffusion layer and the drain diffusion layer. The gate section, the drain diffusion region, and the source diffusion region constitute a switching transistor 11, which is provided in the memory cell section 10. Similarly, a logic transistor 21 is provided in the peripheral cell section 20.

An interlayer insulating film 107 is formed on the substrate 100, covering the transistors 11 and 21. The interlayer-insulating film 107 has a flat upper surface. The interlayer insulating film 107 can be made of boron phosphorous silicate glass (BPSG), plasma-tetra ethoxy silane (P-TEOS), or the like. The interlayer insulating film 107 has contact holes that extend to the source diffusion layer and the drain diffusion layer, respectively. Metal fills the contact holes, forming plug electrodes 108a, 108b and 108c. The plug electrode 108a is connected to the source diffusion layer of the transistor 11. The plug electrode 108b is connected to the drain diffusion layer of the transistor 11. The plug electrode 108c is connected to the source diffusion layer of the transistor 21. The plug electrodes 108a, 108b and 108c may be made of, for example, tungsten (W) or polycrystalline silicon doped with impurities.

On the plug electrode 108b and a part of the interlayer insulating film 107, a lower electrode 111, a ferroelectric film 112 and an upper electrode 113 are laid one on another in the order mentioned. The electrodes 111 and 112 and the ferroelectric film 112 constitute a ferroelectric capacitor 12. The lower electrode 111 is made of any material selected from, for example, Pt, Ir, IrO₂, SRO, Ru and RuO₂. The ferroelectric film 112 is made of any material selected from, for example, PZT and SBT. The upper electrode 113 is made of any material selected from, for example, Pt, Ir, IrO₂, SRO, Ru and RuO₂.

A hydrogen-diffused barrier film 115 is formed on the interlayer insulating film 107, plug electrodes 108a and 108c and ferroelectric capacitor 12. The barrier film 115 has been formed by atomic layer deposition (ALD) or sputtering. The barrier film 115 is made of, for example, Al₂O₃, TiO₂, or SiN.

An interlayer insulating film 116 is formed on the hydrogen-diffused film 115 and has a flat surface. This interlayer insulating film can be made of, for example, P-TEOS, O₃-TEOS, SOG, Low-k film (SiOF or SiOC), or SiN. Selected parts of the interlayer insulating film 116 and hydrogen-diffused film 115 are removed, thus making contact holes, which extend to the plug electrode 108a, upper electrode 113 and plug electrode 108c. Metal is filled in these contact holes, thereby forming plug electrodes 117a, 117b and 117c. The plug electrodes 117a, 117b and 117c are made of any material selected from, for example, W, Al, TiN, Cu, Ti, Ta and TaN. They have been deposited by MOCVD, sputtering, electroplating, sputtering-reflow or the like.

A conductive film is deposited, as wiring material, on the plug electrodes 117a, 117b and 117c and the interlayer insulating film 116. The conductive film is subjected to selective etching such as RIE, forming first wires 121a and 121b. The wires 121a and 121b are made of any material selected from, for example, W, Al, TiN, Cu, Ta and TaN.

An interlayer insulating film 122 is formed on the interlayer insulating film 116, thus covering the wires 121a and 121b. The interlayer insulating film 122 is processed, thus acquiring a flat surface. This insulting film 122 may be made of, for example, P-TEOS, O₃-TEOS, SOG, Low-k film (SiOF, SiOC) or SiN.

The interlayer insulating film 122 has contact holes and grooves, which extend to the wires 121a and 121b. These contact holes and grooves are filled with metal material, and the masses of metal material in the contact holes and grooves are processed at top, acquiring a flat surface. Thus, contact plugs 123a and 123b and second wires 124a and 124b are formed. This method of forming the plugs and wires is known as damascene process. The contact plugs 123a and 123b and second wires 124a and 124b are made of any material selected from, for example, W, Al, TiN, Cu, Ti, Ta and TaN. They have been deposited by MOCVD, sputtering, electroplating, sputtering-reflow or the like. The damascene process, which forms the contact plugs 123a and 123b and wires 124a and 124b, is repeated, thus providing multi-layered wires.

A hydrogen-diffused barrier film 131 is formed on the interlayer insulating film 122, covering the wires 124a and 124b. On this barrier film 131, damascene wires are formed.

The wire 121a, i.e., the first wire provided above the ferroelectric capacitor 12, has been formed by depositing wire material and then patterning the material layer deposited. When the conductive film, i.e., wire-material film, is deposited on the entire surface, it connects the plug electrodes 117a and 117b. As a result, the ferroelectric capacitor 12 is electrically connected to the substrate 100. This connection is maintained after the conductive film is patterned. This prevents charging damages which may otherwise develop during the RIE performed to make grooves to form first wires if the damascene process is carried out to form the conventional first wires. Even when the second wires, third wires and so forth are formed, the ferroelectric capacitor 12 remains electrically connected to the substrate 100 by the first wire 121a. Hence, the ferroelectric capacitor 12 is not debased even if the damascene process is carried out to provide high-performance logic circuits. FeRAMs and high-performance logic circuits can be fabricated on the same substrate.

In this embodiment, the first wire 121a that should be connected to the upper electrode 113 of the ferroelectric capacitor 12 is formed, not by the damascene process. Rather, the first wire 121a is formed by RIE after a conductive film is deposited on the entire surface. The first wire 121a is an RIE wire, not a damascene wire. This is why charging damages are avoided, which may develop if the damascene process is carried out. Nevertheless, high-performance logic cells can have damascene wires as is desired. As a result, high-performance logic elements and FeRAMs can be fabricated on the same substrate.

That is, charging damages to the ferroelectric capacitor can be suppressed, while employing damascene structure to the multi-layered wires. Therefore, this embodiment, i.e., an ferroelectric memory, can have good ferroelectric characteristic and improved element characteristic.

### Second Embodiment

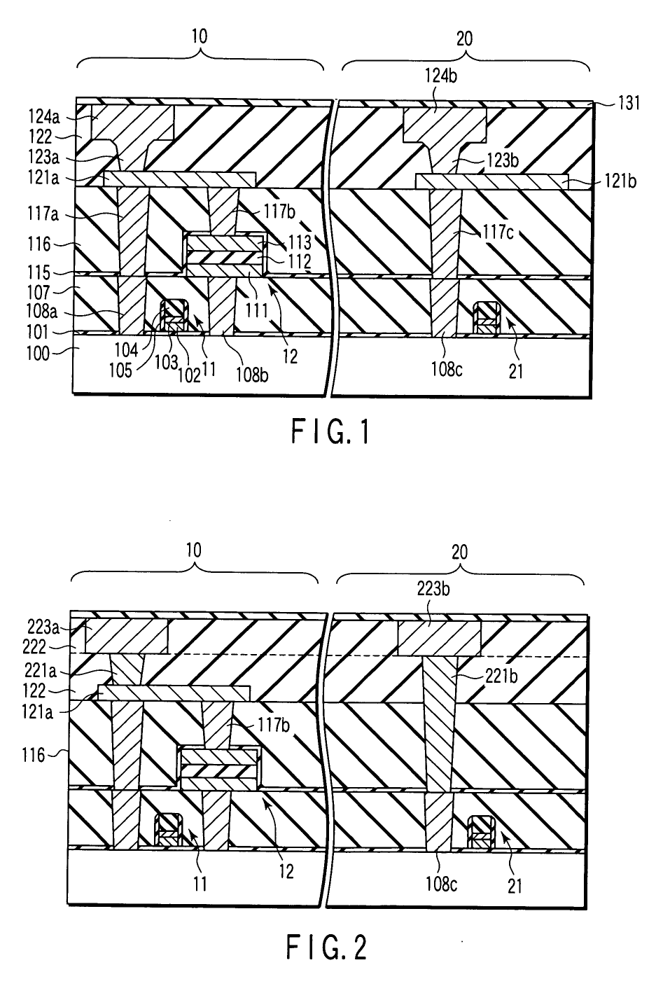

FIG. 2 is a sectional view showing the structure of an FeRAM cell according to the second embodiment of this invention. The components identical to those shown in FIG. 1 are designated at the same reference numerals and will not be described in detail.

This embodiment differs from the first embodiment in the wiring structure in the peripheral cell section 20. More precisely, the wiring structure in the ferroelectric memory cell section 10 and the wiring structure in the peripheral cell section 20 differ from each other.

In this embodiment, the wire 121a of the ferroelectric capacitor 12 is used as a local wire. In the peripheral cell section 20, a contact plug 221b and a second wire 223b are connected to the plug electrode 108c.

In the memory cell section 10, a contact plug 221a and a second wire 223a formed by damascene process are provided and connected to the first wire 121a that is connected to the upper electrode 113 of the ferroelectric capacitor 12 as in the first embodiment. In the peripheral cell section 20, the first wire 121b is not formed, and the interlayer insulating films 122 and 116 have a contact hole that reaches the plug electrode 108c. The contact plug 221b is formed in this contact hole, and the second wire 223b is formed on the contact plug 221b by means of damascene process. Note that the interlayer insulating film 122 is deposited to such thickness that its upper surface lies at the same level as the upper ends of the contact plugs 221a and 221b. On the interlayer insulating film 122, an interlayer insulating film 222 is formed. The second wires 223a and 223b are provided in this interlayer insulating film 222.

With this embodiment, it is possible to form a wiring structure that can suppress damages to the ferroelectric capacitor in the ferroelectric memory-cell section, while an appropriate wiring structure is provided in the standard logic circuit. This renders it even easier to fabricate FeRAMs and high-performance logic elements on the same substrate.

### Third Embodiment

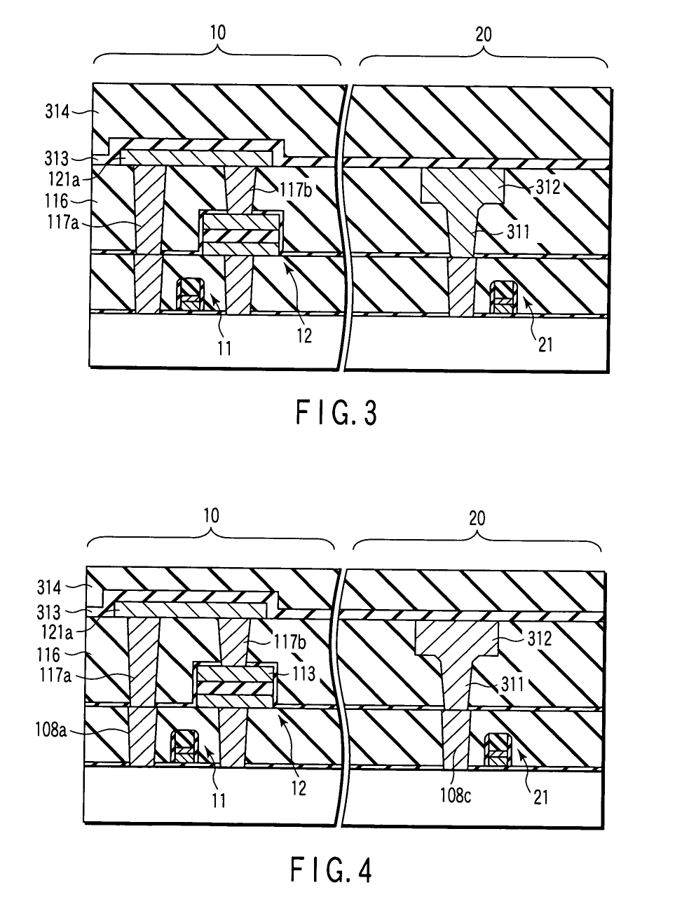

FIG. 3 is a sectional view depicting the structure of an FeRAM cell according to the third embodiment of this invention. The components identical to those shown in FIG. 1 are designated at the same reference numerals and will not be described in detail.

This embodiment differs from the first embodiment in the wiring structure in the peripheral cell section 20. More precisely, in the peripheral cell section 20, a wire 312 and a contact plug 311 are formed in the interlayer insulating film 116 by damascene process after the contact plugs 117a and 117b are formed in the ferroelectric memory cell section 10. Thereafter, a wire 121a, i.e., first wire, is formed above the ferroelectric capacitor 12.

A hydrogen-diffused barrier film 313 is formed on the interlayer insulating film 116 and wires 121a and 312. An interlayer insulating film 314 is formed on the hydrogen-diffused barrier film 313. In this case, too, damascene wires to be connected to the wires 121a and 312, respectively, may be formed in the interlayer insulating film 314 as in the first embodiment.

This embodiment achieves the same advantages as the first embodiment. In addition, this embodiment is advantageous in that the aspect of the contact plug 311 formed in the peripheral cell section 20 can be reduced, rendering the manufacture process easy and the elements smaller.

### Fourth Embodiment

FIG. 4 is a sectional view illustrating the structure of an FeRAM cell according to the fourth embodiment of this invention. The components identical to those shown in FIG. 1 are designated at the same reference numerals and will not be described in detail.

This embodiment differs from the third embodiment in the process of forming the contact plug 311 and wire 312. In the present embodiment, the contact plug 311 in the peripheral cell section 20 is formed at the same time the contact plug 117a is formed in the ferroelectric memory cell section 10. That is, a contact hole reaching the plug electrode 108c and a wire groove are made in the peripheral cell section 20, while contact holes reaching the plug electrode 108a and upper electrode 113, respectively, are being in the memory cell section 10. The contact holes are filled with metal material, thereby forming plug electrodes 117a and 117b, contact plug 311 and wire 312.

The contact holes can be made to provide this FeRAM cell in a small number of steps. Further, the process of lithography can be simplified.

### Fifth Embodiment

FIG. 5 is a sectional view showing the structure of an FeRAM cell according to the fifth embodiment of the present invention. The components identical to those shown in FIG. 1 are designated at the same reference numerals and will not be described in detail.

This embodiment differs from the fourth embodiment in that a wire 121b made from the same layer as the wire 121a of the ferroelectric capacitor is formed on the wire 312 in the peripheral cell section 20. Hence, the wire 312 can be protected from damages during the process of forming the wire 121b. In addition, the wire 121b can be used as a local wire in the peripheral cell section 20.

### Sixth Embodiment

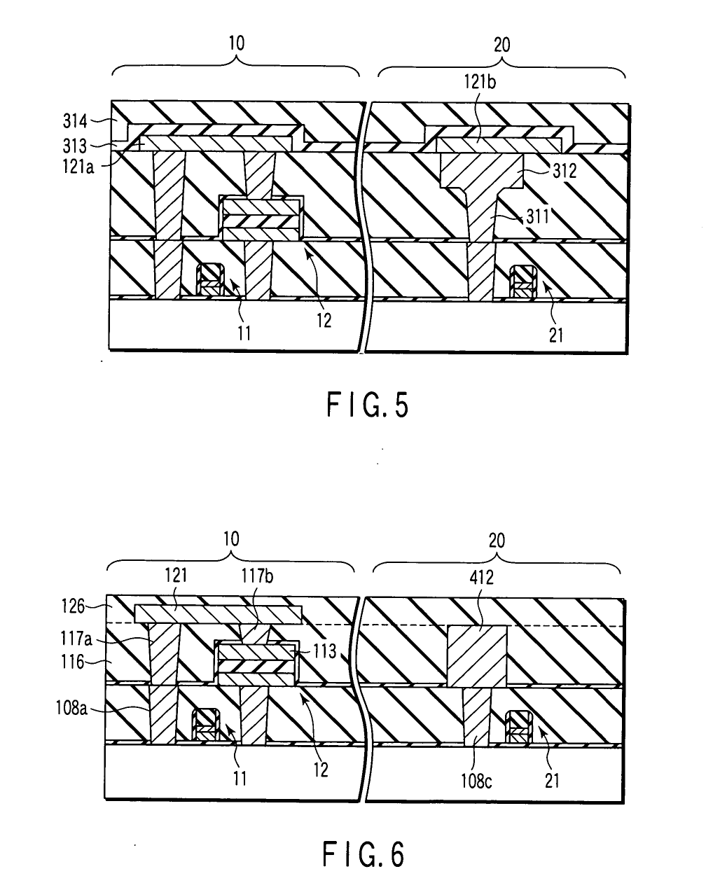

FIG. 6 is a sectional view showing the structure of an FeRAM cell according to the sixth embodiment of the invention. The components identical to those shown in FIG. 1 are designated at the same reference numerals and will not be described in detail.

This embodiment differs from the fourth and fifth embodiments in that a wire 412 is formed in the peripheral cell section 20 at the same time the plug electrodes 117a and 117b are formed in the ferroelectric memory cell section 10. That is, a groove for the wire 412, which reaches the plug electrode 108c, is made in the peripheral cell section 20, while contact holes reaching the plug electrode 108a and upper electrode 113 are being made in the memory cell section 10. The contact holes and the groove are filled with metal material, thereby forming the plug electrodes 117a and 117b and forming, at the same time, the wire 412 by damascene process.

As in the first embodiment, an interlayer insulating film 121 is formed on the interlayer insulating film 116, electrically connecting the plug electrodes 117a and 117b to each other. On the interlayer insulating film 121 there is formed an interlayer insulating film 126.

Hence, it suffices to use only one mask to make the contact hole 117a and the wire groove 412. In other words, two masks need not be used, one to make the contact hole 117a and the other to make the wire groove 412.

### Seventh Embodiment

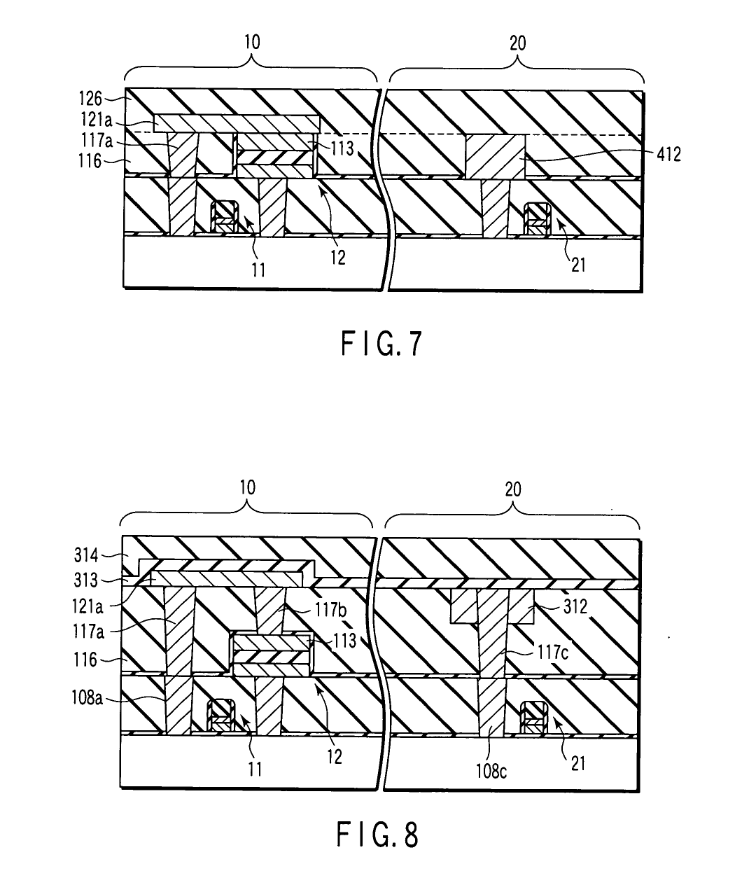

FIG. 7 is a sectional view depicting the structure of an FeRAM cell according to the seventh embodiment of the present invention. The components identical to those shown in FIG. 1 are designated at the same reference numerals and will not be described in detail.

This embodiment differs from the sixth embodiment in that the plug electrode 117b is not formed. After the contact hole for the plug electrode 117a and the groove for the damascene wire 412 are filled with metal material, CMP is performed, making the upper surface flat, until the upper electrode 113 of the ferroelectric capacitor 12 appear at the upper surface. Thus, no contacts need to be provided on the ferroelectric capacitor 12.

### Eighth Embodiment

FIG. 8 is a sectional view showing the structure of an FeRAM cell according to the eighth sixth embodiment of this invention. The components identical to those shown in FIG. 1 are designated at the same reference numerals and will not be described in detail.

This embodiment differs from the third embodiment in two respects. First, the contact plug formed in the peripheral cell section 20 (in the third embodiment) severs as a contact plug in the ferroelectric memory cell section 10, as well. Second, the wire 312 of the logic cell is formed on the contact plug formed in the peripheral cell section 20.

More precisely, three contact holes reaching the plug electrode 108a, upper electrode 113 and plug electrode 108c, respectively, are made in the interlayer insulating film 116 and filled with metal material, thereby forming plug electrodes 117a, 117b and 17c. Then, a wire groove reaching the plug electrode 117c is made in the peripheral cell section 20. The wire groove is filled with metal material, thus forming a wire 312 by damascene process.

### Ninth Embodiment

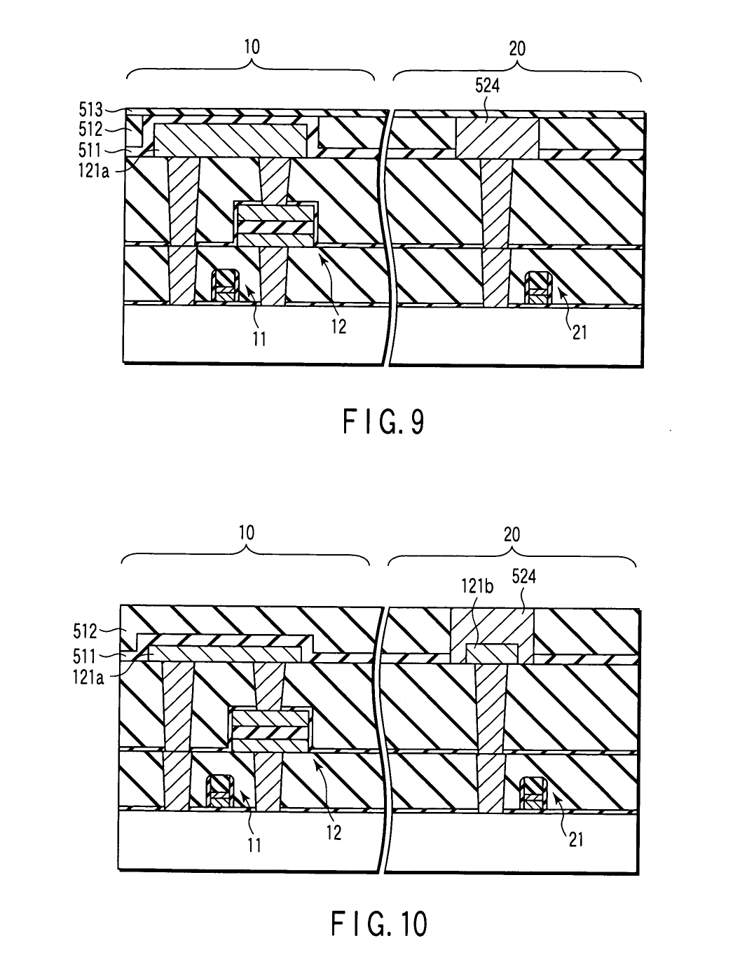

FIG. 9 is a sectional view illustrating the structure of an FeRAM cell according to the ninth embodiment of the present invention. The components identical to those shown in FIG. 1 are designated at the same reference numerals and will not be described in detail.

This embodiment differs from the second embodiment in the method of forming wires in the peripheral cell section 20. After the wire 121a is formed in the peripheral cell section 20, an etching stopper film 511 is deposited, covering the wire 121a, and an interlayer insulating film 512 is deposited on the stopper film 511. The interlayer insulating film 512 is subjected to CMP, acquiring a flat top, until the stopper film 511 is exposed at its upper surface. Then, a wire groove is made in the peripheral cell section 20, and a wire 524 is formed in the groove by damascene process. Thus, the ferroelectric memory cell section 10 and the peripheral cell section 20 can share the same contact. This simplifies the process of fabricating the FeRAM cell.

### Tenth Embodiment

FIG. 10 is a sectional view showing the structure of an FeRAM cell according to the tenth embodiment of this invention. The components identical to those shown in FIG. 1 are designated at the same reference numerals and will not be described in detail.

This embodiment differs from the ninth embodiment in that a wire 121b is formed in the peripheral cell section 20, in the same way as in the ferroelectric memory cell section 10. Hence, the surface of each contact plug can be protected when a wire groove is made in the peripheral cell section 20.

### Eleventh Embodiment

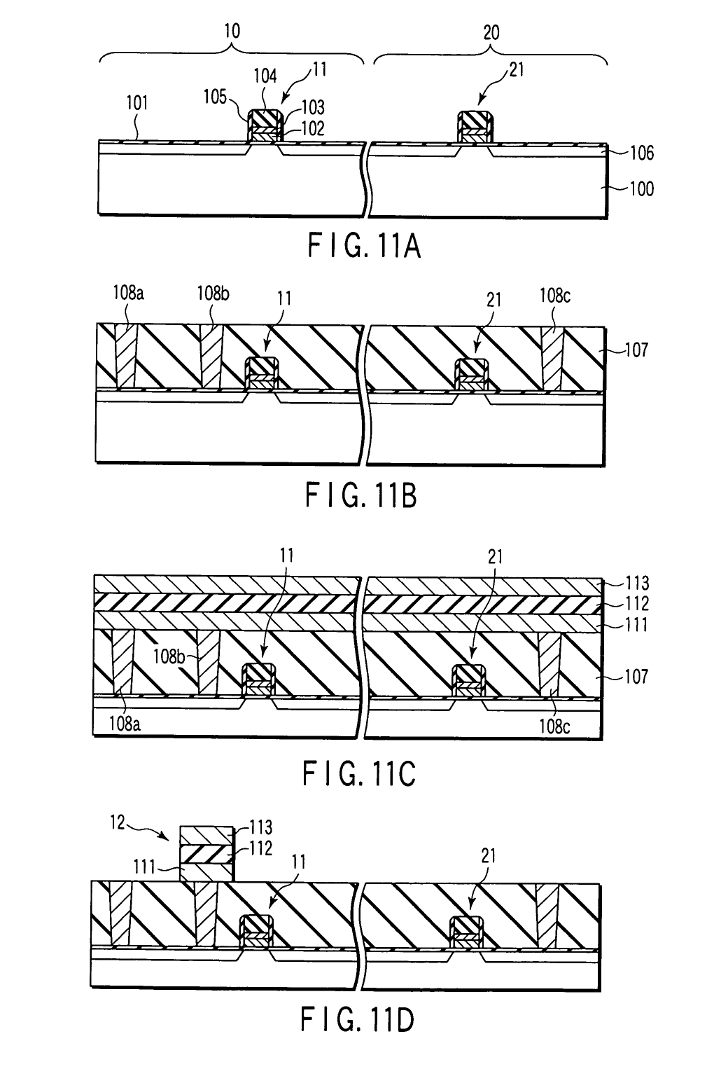

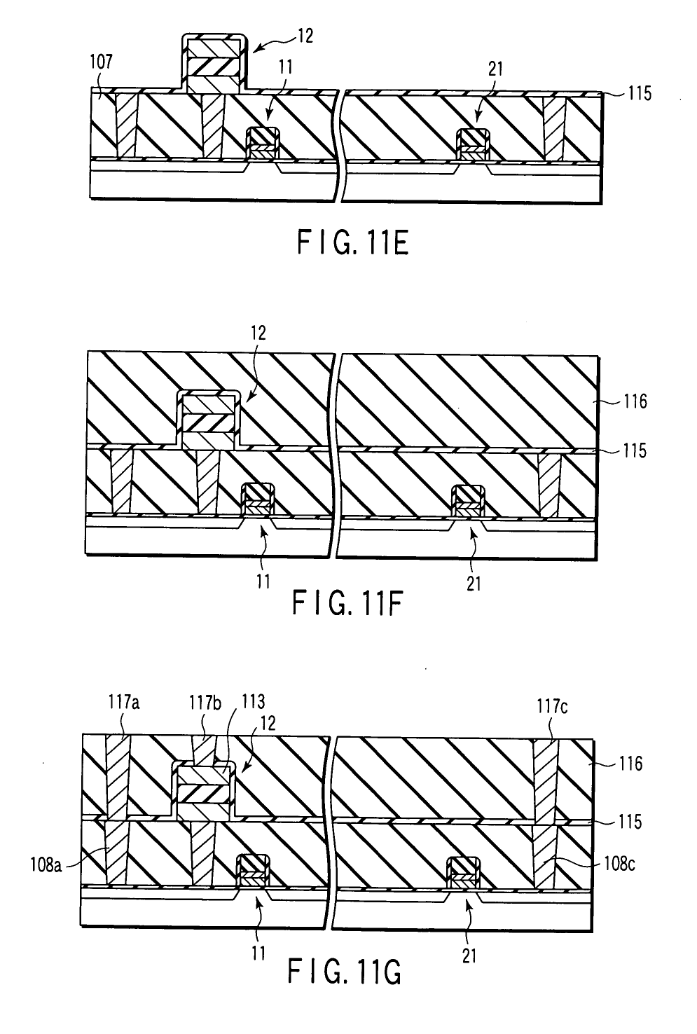

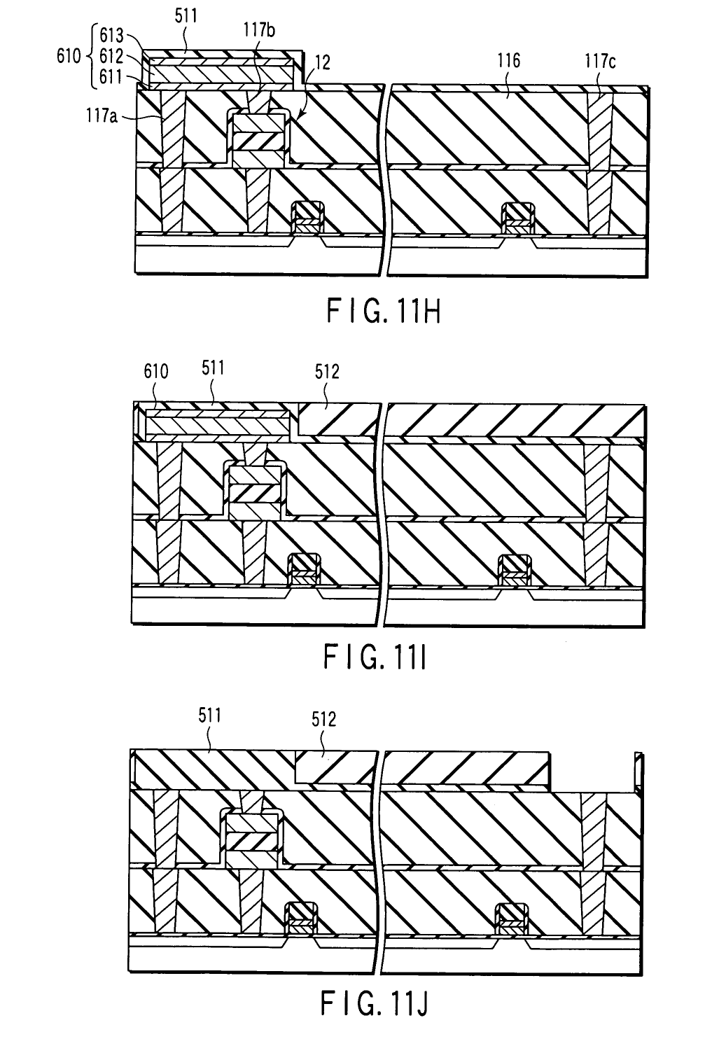

FIGS. 11A to 11J are sectional views explaining the steps of manufacturing an FeRAM cell according to the eleventh embodiment of the present invention. The components identical to those shown in FIG. 1 are designated at the same reference numerals and will not be described in detail.

This embodiment is a method of manufacturing the FeRAM according to the ninth embodiment described above.

First, as FIG. 11A shows, a gate insulating film 101 made of, or example, SiO₂ is formed on the entire surface of a silicon substrate 100. On the gate insulating film 101, a lower gate-electrode layer of polycrystalline silicon, an upper gate-electrode layer of tungsten silicide and a cap layer of SiN are formed, one on another in the order they are mentioned. These layers are gate-patterned, providing gate units in the ferroelectric memory cell section 10 and peripheral cell section 20. Each gate unit comprises a lower gate electrode 102, an upper gate electrode 103 and a cap layer 104. Then, widewall insulating films 105 are formed on the sidewalls of each gate unit. Thus, transistors 11 and 21 are provided in the memory cell section 10 and peripheral cell section 20, respectively.

As FIG. 11B shows, an interlayer insulating film 107 made of BPSG or P-TEOS is deposited on the substrate 100, covering the transistors 11 and 21. The interlayer insulating film 107 is processed, acquiring a flat upper surface. Then, contact holes are made in the interlayer insulating film 107, each reaching the source/drain diffusion layer 106 of one transistor. The contact holes are filled with metal material such as tungsten (W) or polycrystalline silicon. Plug electrodes 108a and 108b are thereby formed in the contact holes.

As FIG. 11C depicts, on the interlayer insulating film 107 and plug electrodes 108a and 108b, a lower-electrode film 111, a ferroelectric film 112 and an upper-electrode film 113 are deposited, one on another in the order mentioned. The lower-electrode film 111 is made of Pt, Ir, IrO₂, SRO, Ru or RuO₂. The ferroelectric film 112 is made of PZT, SBT or the like. The upper-electrode film 113 is made of Pt, Ir, IrO₂, SRO, Ru or RuO₂.

As shown in FIG. 11D, the upper-electrode film 113, ferroelectric film 112 and lower-electrode film 111 are patterned by means of RIE. A ferroelectric capacitor is thereby provided, which has a lower electrode 111, ferroelectric film 112 and an upper electrode 113.

Then, as FIG. 11E shows, a hydrogen-diffused barrier film 115 is deposited on the interlayer insulating film 107 by means of ALD process or sputtering. The barrier film 115 is made of, for example, Al₂O₃, TiO₂, or SiN.

As shown in FIG. 11F, an interlayer insulating film 116 made of P-TEOS, O3-TEOS, SOG, Low-k film (e.g., SiOF or SiOC) or SiN is deposited on the hydrogen-diffused barrier film 115. The film 116 is processed, acquiring a flat upper surface.

Next, selected parts of the hydrogen-diffused barrier film 115 and interlayer insulating film 116 are removed as shown in FIG. 11G. Contact holes reaching the plug electrode 108a, upper electrode 113 and plug electrode 108c, respectively, are thereby made. The contact holes are filled with metal material such as W, Al, TiN, Cu, Ti, Ta or TaN by MOCVD, sputtering, electroplating, sputtering-reflow or the like. The masses of metal material are processed, each acquiring a flat top, until the interlayer insulating film 116 is exposed at top. Plug electrodes 117a, 117b and 117d are thereby formed.

As FIG. 11H shows, a three-layer wire film 610 composed of a TiN barrier layer 611, an Al layer 612 and an TiN barrier layer 613 is deposited on the interlayer insulating film 116, covering the plug electrodes 117a, 117b and 117d. The three-layer wire film 10 is pattern by RIE. The wire film 610 is connected to the plug electrodes 117a and 117b. Hence, the wire 610 and plug electrodes 117a and 117b electrically connect the upper electrode 113 of the ferroelectric capacitor 12 to the source/drain diffusion layer 106.

As FIG. 11I depicts, an etching stopper film 511 is deposited, and an interlayer insulating film 512 is deposited. The interlayer insulating film 512 is subjected to CMP until the stopper film 511 is exposed at top. The substrate therefore acquired a flat upper surface.

As FIG. 11J shows, in the interlayer insulating film 512 and stopper film 511, a wire groove is formed, which reaches the plug electrode 117c.

Thereafter, wiring material is deposited on the entire surface of the substrate, and CMP or the like is performed, rendering the structure flat at top. The wire groove is thereby filled with wire material, forming a wire (i.e., second wire) 524. The structure shown in FIG. 9 is thereby obtained.

In this embodiment, the first wire 121a electrically connected to the ferroelectric capacitor 12 has thus been formed by performing RIE on a wire-material film deposited. This suppresses the characteristic degradation resulting from the charging damages to the ferroelectric capacitor. It is therefore possible to provide a hybrid device that includes a high-performance logic having damascene wires.

Modification

The present invention is not limited to the embodiments described above. In the embodiments, the first wire connected to the upper electrode of the ferroelectric capacitor is a RIE wire, while the other wires are either RIE wires or damascene wires. Nonetheless, only the wire connected to the upper electrode of the ferroelectric capacitor needs to be a RIE wire, because the invention relates to a semiconductor device that has damascene wires. The material of the ferroelectric film of the ferroelectric capacitor and that of the electrodes thereof may be changed in accordance with the specification. Further, the material of each wire may be changed, too, in accordance with the specification.

The embodiments described above are ferroelectric memories each comprising TC unit cells connected in series. The invention is not limited to this type of a ferroelectric memory, nevertheless. It can be applied to memories of various types that comprise ferroelectric capacitors.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a switching transistor which is formed on the substrate;
a ferroelectric capacitor which is formed on the substrate and includes a lower electrode, an upper electrode and a ferroelectric film held between the lower and upper electrodes;
a first wire which is formed on the ferroelectric capacitor, electrically connected to the upper electrode of the ferroelectric capacitor, and formed from a deposited wire-material film; and
a second wire which is provided on the first wire and formed by damascene process.

2. The semiconductor device according to claim 1, wherein the transistor is formed in a surface region of the substrate, a first interlayer insulating film is formed on the substrate and covers the transistor, a first plug electrode is formed in the first interlayer insulating film and electrically connected to the surface of the substrate, the ferroelectric capacitor is formed on the first interlayer insulating film, and the lower electrode of the ferroelectric capacitor is connected to the first plug electrode.

3. The semiconductor device according to claim 2, wherein a second interlayer insulating film is formed on the first interlayer insulating film and covers the ferroelectric capacitor, a second plug electrode is formed in the second interlayer insulating film and electrically connected to the upper electrode of the ferroelectric capacitor, and the first wire is formed on the second interlayer insulating film and has a part electrically connected to the second plug electrode.

4. The semiconductor device according to claim 3, wherein a third plug electrode is formed in the first interlayer insulating films and the second interlayer insulating films and electrically connected to a part of the substrate, and a part of the first wire is connected to the third plug electrode.

5. The semiconductor device according to claim 3, wherein a third interlayer insulating film is formed on the second interlayer insulating film and covers the first wire, a contact hole and a wire groove in the third interlayer insulating film reach the first wire, and the second wire is buried in the contact hole and the wire groove.

6. A semiconductor device comprising:
a semiconductor substrate;
a memory cell section which is formed on a region of the substrate and has a memory cell that comprises a switching transistor and a ferroelectric capacitor including a lower electrode, an upper electrode and a ferroelectric film held between the lower and upper electrodes;
a peripheral cell section which is formed on another region of the substrate and has a transistor;
a first wire which is connected to the upper electrode of the ferroelectric capacitor and formed from a deposited wire-material film; and
a second wire which is formed in the peripheral section and formed by damascene process.

7. The semiconductor device according to claim 6, wherein each of the transistors is formed in a surface region of the substrate, a first interlayer insulating film is formed on the substrate and covers each of the transistors, a first plug electrode is formed on the first interlayer insulating film and electrically connected to the surface of the substrate, the ferroelectric capacitor is formed in the first interlayer insulating film, and the lower electrode of the ferroelectric capacitor is connected to the first plug electrode.

8. The semiconductor device according to claim 7, wherein a second interlayer insulating film is formed on the first interlayer insulating film and covers the ferroelectric capacitor, a second plug electrode is formed in the second interlayer insulating film and electrically connected to the upper electrode of the ferroelectric capacitor, and the first wire is formed on the second interlayer insulating film and has a part electrically connected to the second plug electrode.

9. The semiconductor device according to claim 8, wherein a third interlayer insulating film is formed on the first and second interlayer insulating films and electrically connected to a part of the substrate, and the first wire has a part electrically connected to the third plug electrode.

10. The semiconductor device according to claim 8, wherein a third interlayer insulating film is formed on the second interlayer insulating film and covers the first wire, a wire groove is made in the third interlayer insulating film, and the second wire is buried in the wire groove.

11. The semiconductor device according to claim 10, wherein the second wire is formed also on the first wire which is formed in the memory cell section.

12. The semiconductor device according to claim 8, wherein a wire groove is made in the second interlayer insulating film formed in the peripheral cell section, and the second wire is buried in the wire groove.

13. A method of manufacturing a semiconductor device, comprising:
forming a switching transistor on a semiconductor substrate;
depositing a first interlayer insulating film on the substrate, covering the transistor;
forming a ferroelectric capacitor including a lower electrode, a ferroelectric film and an upper electrode on the first interlayer insulating film, sequentially one on another;
depositing a second interlayer insulating film on the first interlayer insulating film, covering the ferroelectric capacitor;
forming a plug electrode in the second interlayer insulating film, said plug electrode being electrically connected to the upper electrode of the ferroelectric capacitor;
forming a conductive film on the second interlayer insulating film and the plug electrode;
patterning the conductive film, thereby forming a first wire; and
forming a second wire on the first wire by damascene process.

14. The method according to claim 13, wherein a plug electrode is formed in the first interlayer insulating film before the ferroelectric capacitor is formed, said plug electrode being connected to the substrate, and the lower electrode of the ferroelectric capacitor is made to contact the plug electrode while the ferroelectric capacitor is being formed.

15. The method according to claim 13, wherein a first plug electrode and a second plug electrode are formed in the first interlayer insulating film before the ferroelectric capacitor is formed, the first and second plug electrodes being connected to the substrate, and the lower electrode of the ferroelectric capacitor is made to contact the first plug electrode while the ferroelectric capacitor is being formed; and a third plug electrode is formed in the second interlayer insulating film at the same time the plug electrode connected to the upper electrode of the ferroelectric capacitor is formed, said third plug electrode contacting the second plug electrode connected to the substrate and thereby being connected to the substrate.

16. The method according to claim 15, wherein the conductive film is patterned by selective RIE in order that the first wire is connected to the plug electrode connected to upper electrode of the ferroelectric capacitor and the third plug electrode connected to the substrate by the second plug electrode.

17. The method according to claim 13, wherein the damascene process is performed to form the second wire, first by depositing a third interlayer insulating film on the second interlayer insulating film, covering the first wire, then by making a contact hole and a wire groove in the third interlayer insulating film, and finally by burying a conductive film in the contact hold and the wire groove.
